(19) United States
(12) Patent Application Publication
(10) Pub. No.: US 2014/0306243 A1
(43) Pub. Date: Oct. 16, 2014

(54) LIGHT EMITTING DEVICE

(71) Applicant: WINTEK CORPORATION, Taichung City (TW)

(72) Inventors: Ming-Chuan Lin, Taichung City (TW); Zhi-Ting Ye, Miaoli County (TW); Wen-Chieh Wu, New Taipei City (TW)

(73) Assignee: WINTEK CORPORATION, Taichung City (TW)

(21) Appl. No.: 14/224,050

(22) Filed: Mar. 24, 2014

(30) Foreign Application Priority Data
Apr. 10, 2013 (TW) 102206528

(51) Int. Cl. H01L 25/13

(52) U.S. Cl. CPC H01L 25/13
USPC 257/88

(57) ABSTRACT

A light emitting device includes a frame, a plurality of first light emitting units and a plurality of second light emitting units. The frame includes a base, a plurality of first pillars and a plurality of second pillars, wherein the first pillars and the second pillars are extended from a periphery of the base and arranged interlacedly, the first pillars are bent inwardly with respect to the base, and the second pillars are bent outwardly with respect to the base. Each of the first light emitting units is disposed on one of the first pillars. Each of the second light emitting units is disposed on one of the second pillars.

### BACKGROUND OF THE INVENTION

1. Field of the Invention

The invention relates to a light emitting device and, more particularly, to a light emitting device capable of emitting light with a large angle and avoiding generating a dark area.

2. Description of the Prior Art

Referring to FIGS. 1 and 2, FIG. 1 is a perspective view illustrating a light emitting device 1 of the prior art, and FIG. 2 is a cross-sectional view illustrating the light emitting device 1 along a line A-A shown in FIG. 1. As shown in FIGS. 1 and 2, the light emitting device 1 comprises a frame 10 and a plurality of light emitting units 12. The light emitting unit 12 is a light emitting diode capable of emitting light from opposite sides. The frame 10 comprises a base 100 and a plurality of pillars 102, wherein the pillars 102 are extended from a periphery of the base 100 and each of the pillars 102 is bent outwardly with respect to the base 100 with the same angle. Since the pillars 102 are bent outwardly with respect to the base 100 and the light emitting units 12 are light emitting diodes capable of emitting light from opposite sides, the light emitting angle of the light emitting device 1 can be raised accordingly. However, since each of the pillars 102 is bent outwardly with respect to the base 100 with the same angle, there will be a dark area over each of the light emitting units 12. Consequently, the light emitting performance of the light emitting device 1 is influenced.

### SUMMARY OF THE INVENTION

An objective of the invention is to provide a light emitting device capable of emitting light with a large angle and avoiding generating a dark area.

According to an embodiment of the invention, a light emitting device comprises a frame, a plurality of first light emitting units and a plurality of second light emitting units. The frame comprises abase, a plurality of first pillars and a plurality of second pillars, wherein the first pillars and the second pillars are extended from a periphery of the base and arranged interlacedly, the first pillars are bent inwardly with respect to the base, and the second pillars are bent outwardly with respect to the base. Each of the first light emitting units is disposed on one of the first pillars. Each of the second light emitting units is disposed on one of the second pillars.

According to another embodiment of the invention, a light emitting device comprises a frame and a plurality of light emitting units. The frame comprises abase and a plurality of pillars, wherein an extending line of a junction between each of the pillars and the base passes through a center of the base, so that the pillars are arranged radially. Each of the light emitting units is disposed on one of the pillars.

As mentioned in the above, the pillars of the invention may be bent inwardly and outwardly with respect to the base and arranged interlacedly, so that the light emitting device is capable of emitting light with a large angle and avoiding generating a dark area over the light emitting units. Furthermore, the extending line of the junction between each pillar and the base may pass through the center of the base so as to arrange the pillars radially. Accordingly, the light emitting device is capable of emitting light with a large angle and avoiding generating a dark area over the light emitting units.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a perspective view illustrating a light emitting device of the prior art.

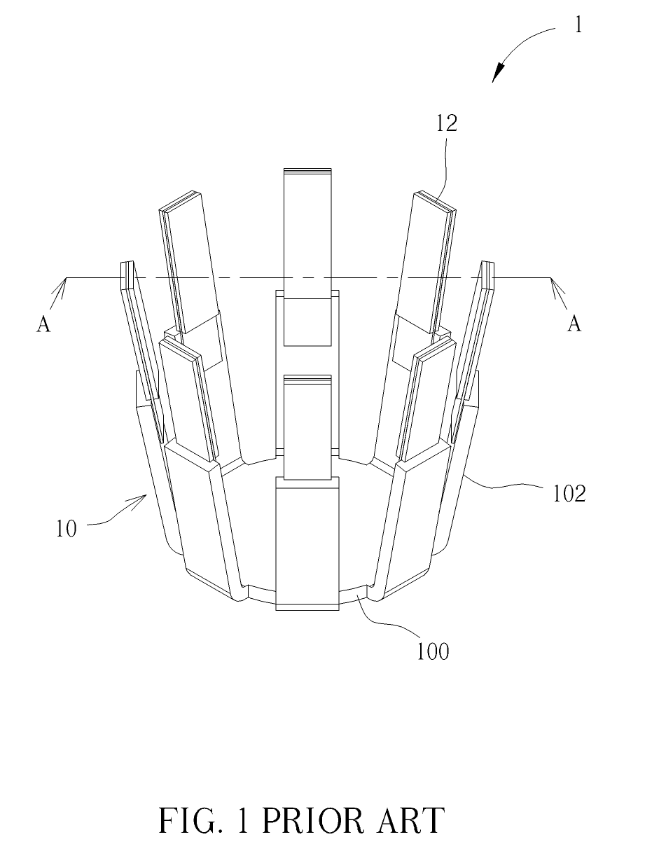

FIG. 2 is a cross-sectional view illustrating the light emitting device along a line A-A shown in FIG. 1.

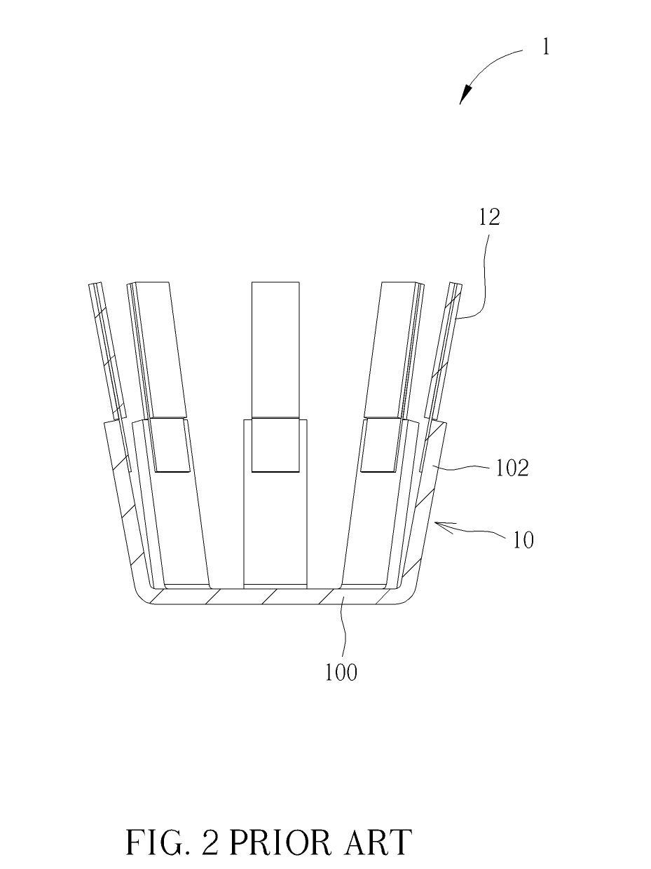

FIG. 3 is a perspective view illustrating a light emitting device according to a first embodiment of the invention.

FIG. 4 is a top view illustrating the light emitting device shown in FIG. 3.

FIG. 5 is a cross-sectional view illustrating the light emitting device along a line B-B shown in FIG. 4.

FIG. 6 is a cross-sectional view illustrating the light emitting device along a line C-C shown in FIG. 4.

FIG. 7 is a top view illustrating a light emitting device according to a second embodiment of the invention.

FIG. 8 is a perspective view illustrating a light emitting device according to a third embodiment of the invention.

FIG. 9 is a top view illustrating the light emitting device shown in FIG. 8.

FIG. 10 is a perspective view illustrating a light emitting device according to a fourth embodiment of the invention.

FIG. 11 is a top view illustrating the light emitting device shown in FIG. 10.

### DETAILED DESCRIPTION

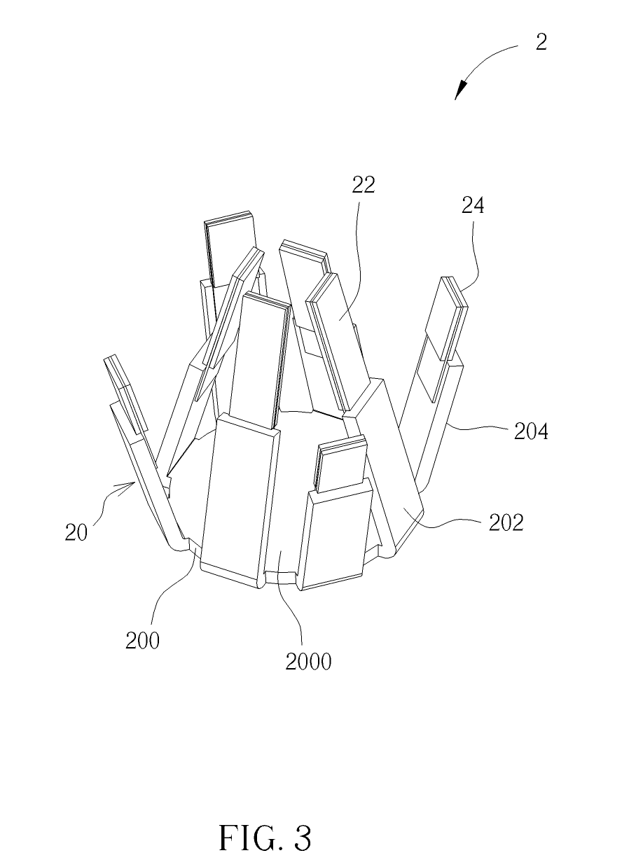

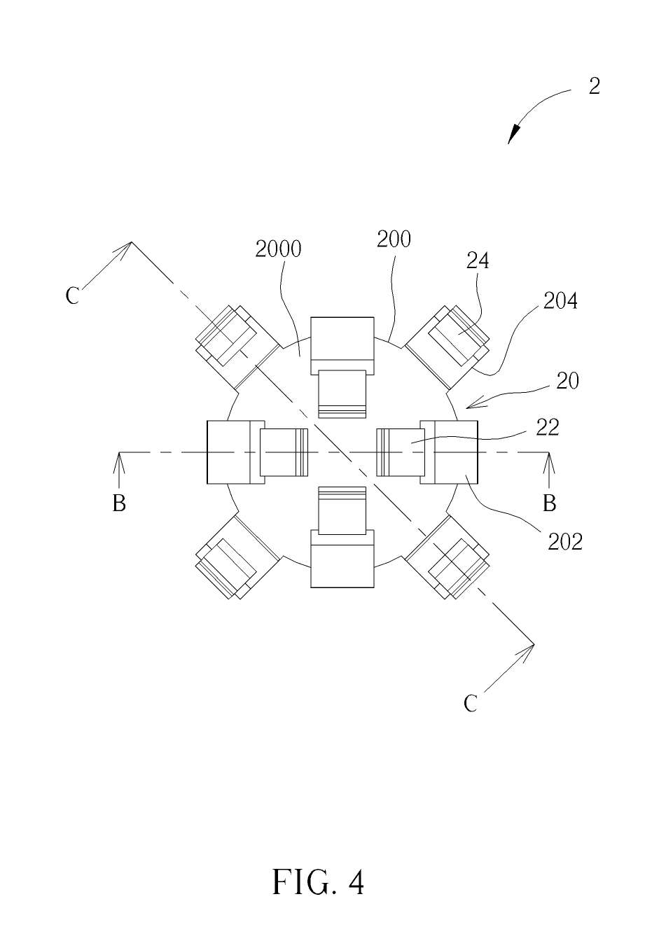

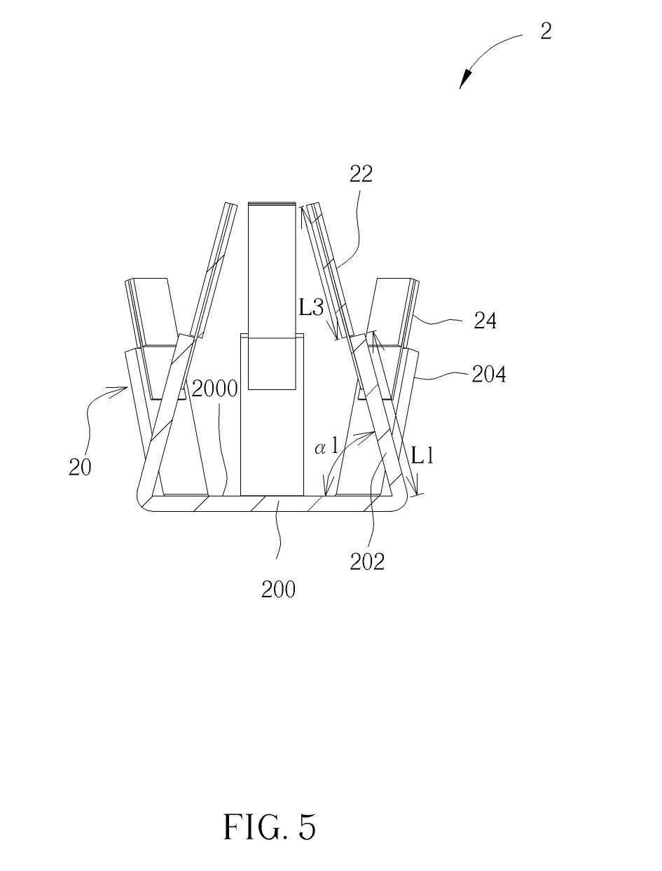

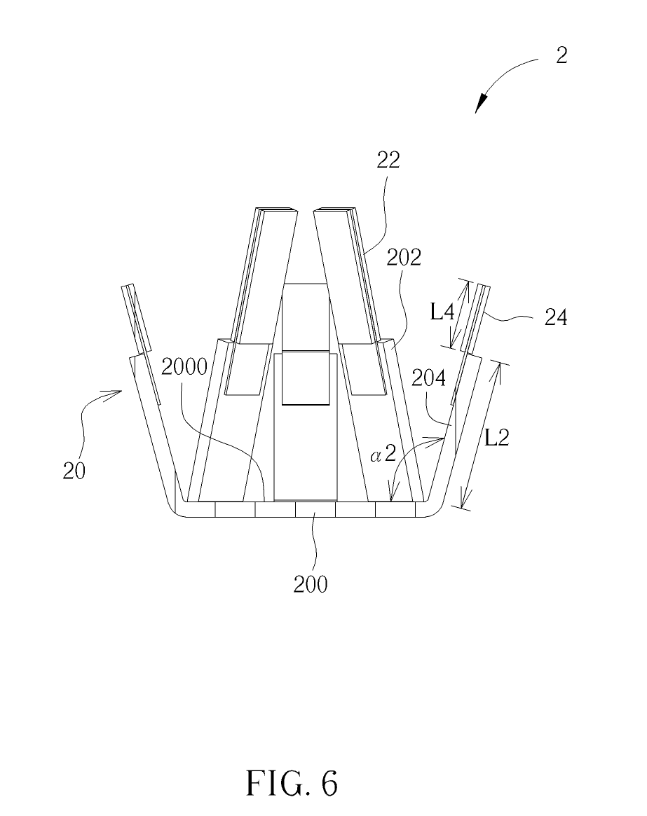

Referring to FIGS. 3 to 6, FIG. 3 is a perspective view illustrating a light emitting device 2 according to a first embodiment of the invention, FIG. 4 is a top view illustrating the light emitting device 2 shown in FIG. 3, FIG. 5 is across-sectional view illustrating the light emitting device 2 along a line B-B shown in FIG. 4, and FIG. 6 is a cross-sectional view illustrating the light emitting device 2 along a line C-C shown in FIG. 4. As shown in FIGS. 3 to 6, the light emitting device 2 comprises a frame 20, a plurality of first light emitting units 22 and a plurality of second light emitting units 24. In this embodiment, the first light emitting units 22 and the second light emitting units 24 may be light emitting diodes capable of emitting light from opposite sides, wherein the light emitting diodes capable of emitting light from opposite sides are well known by one skilled in the art, so their structure and principle will not be depicted herein.

The frame 20 comprises abase 200, a plurality of first pillars 202 and a plurality of second pillars 204, wherein the first pillars 202 and the second pillars 204 are extended from a periphery of the base 200 and arranged interlacedly, the first pillars 202 are bent inwardly with respect to the base 200, and the second pillars 204 are bent outwardly with respect to the base 200. Each of the first light emitting units 22 is disposed on one of the first pillars 202. Each of the second light emitting units 24 is disposed on one of the second pillars 204.

As shown in FIG. 5, since the first pillars 202 are bent inwardly with respect to the base 200, an acute angle α1 is included between each of the first pillars 202 and a surface 2000 of the base 200. As shown in FIG. 6, since the second pillars 204 are bent outwardly with respect to the base 200, an obtuse angle α2 is included between each of the second pillars 204 and the surface 2000 of the base 200. Preferably, the acute angle may be between 72 degrees and 87 degrees and the obtuse angle may be between 93 degrees and 108 degrees. Furthermore, a length L1 of the first pillar 202 may be larger than a length L2 of the second pillar 204, and a length L3 of the first light emitting unit 22 is larger than a length L4 of the second light emitting unit 24. Accordingly, the light emitting device 2 is capable of emitting light with a large angle, and the light emitting ranges of the first light emitting units 22 and the second light emitting units 24 can cover the upper areas for each other, so as to avoid generating a dark area over the first light emitting units 22 and the second light emitting units 24. It should be noted that the acute angle α1, the obtuse angle α2 and the lengths L1-L4 can be determined based on practical applications, so they are not limited to the embodiment shown in FIGS. 5 and 6.

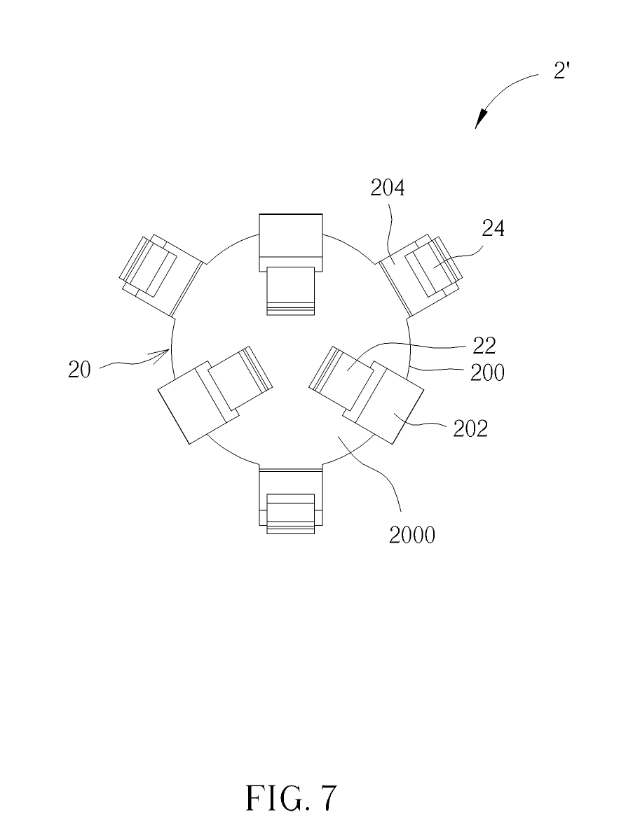

Referring to FIG. 7, FIG. 7 is a top view illustrating a light emitting device 2′ according to a second embodiment of the invention. The main difference between the light emitting device 2′ and the aforesaid light emitting device 2 is that the numbers of the first pillars 202, the second pillars 204, the first light emitting units 22 and the second light emitting units 24 are different. The light emitting device 2′ of this embodiment comprises three first pillars 202, three second pillars 204, three first light emitting units 22 and three second light emitting units 24. It should be noted that the numbers of the first pillars 202, the second pillars 204, the first light emitting units 22 and the second light emitting units 24 can be determined based on practical applications.

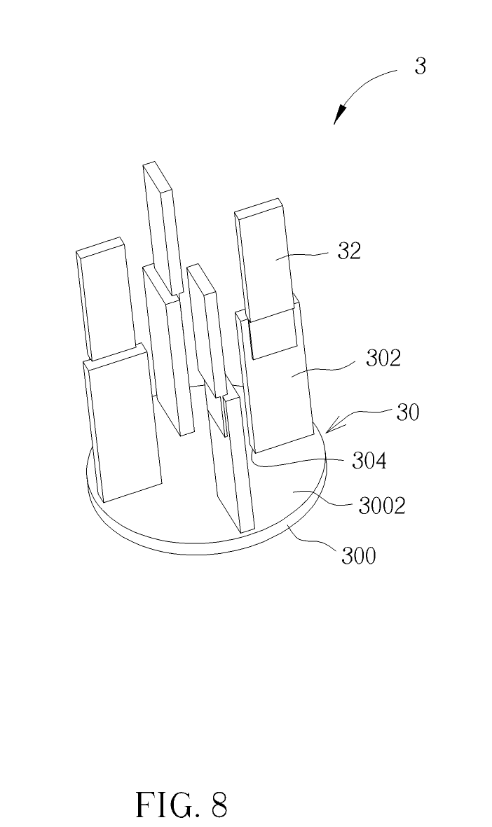

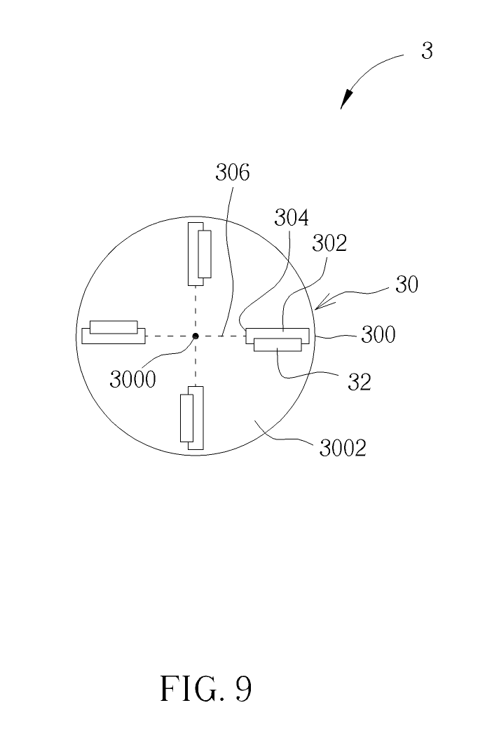

Referring to FIGS. 8 and 9, FIG. 8 is a perspective view illustrating a light emitting device 3 according to a third embodiment of the invention, and FIG. 9 is a top view illustrating the light emitting device 3 shown in FIG. 8. As shown in FIGS. 8 and 9, the light emitting device 3 comprises a frame 30 and a plurality of light emitting units 32. In this embodiment, the light emitting units 32 may be light emitting diodes capable of emitting light from opposite sides, wherein the light emitting diodes capable of emitting light from opposite sides are well known by one skilled in the art, so their structure and principle will not be depicted herein.

The frame 30 comprises a base 300 and a plurality of pillars 302, wherein an extending line 306 of a junction 304 between each of the pillars 302 and the base 300 passes through a center 3000 of the base 300, so that the pillars 302 are arranged radially. Each of the light emitting units 32 is disposed on one of the pillars 302. In this embodiment, each of the pillars 302 is perpendicular to a surface 3002 of the base 300. Since the pillars 302 are arranged radially on the base 300, the light emitting device 3 is capable of emitting light with a large angle and avoiding generating a dark area over the light emitting units 32. In this embodiment, the lengths of the pillars 302 are the same and the lengths of the light emitting units 32 are the same. However, the pillars 302 and the light emitting units 32 may have different lengths as the first pillars 202, the second pillars 204, the first light emitting units 22 and the second light emitting units 24 shown in FIGS. 5 and 6. In other words, at least two of the pillars 302 may have different lengths and at least two of the light emitting units 32 may have different lengths according to practical applications.

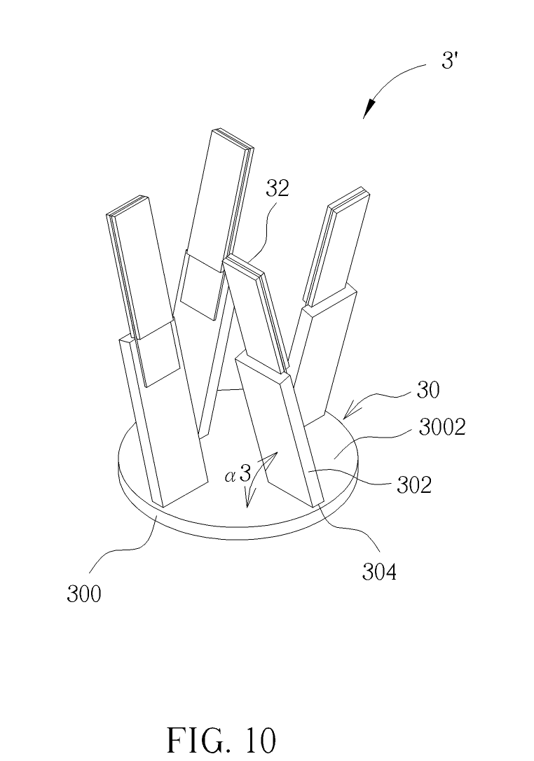

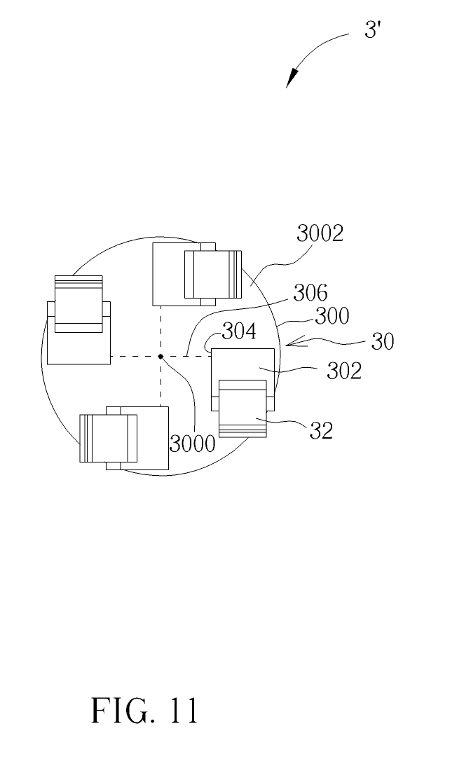

Referring to FIGS. 10 and 11, FIG. 10 is a perspective view illustrating a light emitting device 3′ according to a fourth embodiment of the invention, and FIG. 11 is a top view illustrating the light emitting device 3′ shown in FIG. 10. The main difference between the light emitting device 3′ and the aforesaid light emitting device 3 is that an acute angle α3 is included between each of the pillars 302 of the light emitting device 3′ and the surface 3002 of the base 300. Preferably, the acute angle α3 may be between 72 degrees and 87 degrees.

Compared to the prior art, the pillars of the invention may be bent inwardly and outwardly with respect to the base and arranged interlacedly, so that the light emitting device is capable of emitting light with a large angle and avoiding generating a dark area over the light emitting units. Furthermore, the extending line of the junction between each pillar and the base may pass through the center of the base so as to arrange the pillars radially. Accordingly, the light emitting device is capable of emitting light with a large angle and avoiding generating a dark area over the light emitting units.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A light emitting device comprising:
a frame comprising a base, a plurality of first pillars and a plurality of second pillars, the first pillars and the second pillars being extended from a periphery of the base and arranged interlacedly, the first pillars being bent inwardly with respect to the base, the second pillars being bent outwardly with respect to the base;
a plurality of first light emitting units, each of the first light emitting units being disposed on one of the first pillars; and
a plurality of second light emitting units, each of the second light emitting units being disposed on one of the second pillars.

2. The light emitting device of claim 1, wherein an acute angle is included between each of the first pillars and a surface of the base, and an obtuse angle is included between each of the second pillars and the surface of the base.

3. The light emitting device of claim 2, wherein the acute angle is between 72 degrees and 87 degrees.

4. The light emitting device of claim 2, wherein the obtuse angle is between 93 degrees and 108 degrees.

5. The light emitting device of claim 1, wherein a length of the first pillar is larger than a length of the second pillar.

6. The light emitting device of claim 1, wherein a length of the first light emitting unit is larger than a length of the second light emitting unit.

7. A light emitting device comprising:
a frame comprising a base and a plurality of pillars, an extending line of a junction between each of the pillars and the base passing through a center of the base, so that the pillars are arranged radially; and
a plurality of light emitting units, each of the light emitting units being disposed on one of the pillars.

8. The light emitting device of claim 7, wherein each of the pillars is perpendicular to a surface of the base.

9. The light emitting device of claim 7, wherein an acute angle is included between each of the pillars and a surface of the base.

10. The light emitting device of claim 9, wherein the acute angle is between 72 degrees and 87 degrees.

11. The light emitting device of claim 7, wherein at least two of the pillars have different lengths.

12. The light emitting device of claim 7, wherein at least two of the light emitting units have different lengths.
